(19) United States
(12) Patent Application Publication
(10) Pub. No.: US 2003/0075381 A1
(43) Pub. Date: Apr. 24, 2003

(54) Vehicle speaker

(75) Inventor: Nasser Abo Abdo, Villa Park, CA (US)

Correspondence Address: Irving Keschner, Suite 1150, 21515 Hawthorne Boulevard, Torrance, CA, 90503, US

(73) Assignee: Audiobahn, Inc., Buena Park, CA (US)

(21) Appl. No.: 10/021,488

(22) Filed: Oct. 22, 2001

(51) Int. Cl. H05K 5/00

(52) U.S. Cl. 181/148; 181/153

(57) ABSTRACT

An improved vehicle speaker, or woofer, that is more durable and of a higher quality than those currently available. The speaker includes a cast or machined aluminum basket that increases the strength and rigidity along with efficient cooling required to support a high-power/high-output speaker. An aluminum ring is provided for clamping the speaker assembly in place to the speaker basket. The speaker wires are connected to the speaker using a lug-lock system and has a Faraday cage to reduce interference that otherwise would harm sensitive electronic components. In a second embodiment, a speaker is designed to utilize multiple individual magnetic coils that are stacked in a series/parallel configuration to increase gauss efficiency and voice coil cooling. In a third speaker embodiment, a multi-piece aluminum basket is provided which supports the speaker's reactive and static weight while maintaining the voice coil assembly aligned inside a precision ground gap.

### BACKGROUND OF THE INVENTION

1. Field of the Invention

The present invention provides an improved vehicle loudspeaker having increased strength, rigidity and efficient cooling.

2. Description of the Prior Art

As the number of vehicles and corresponding number of young drivers on the road increase each year, the demand for a unique, powerful vehicle speaker has also increased Although a number of different manufacturers currently supply vehicle speakers of varying sizes and power levels, the speakers tend to be of lower quality with the corresponding decrease in durability. In addition, servicing the speakers in the field is difficult if not impossible.

What is desired is to provide a vehicle speaker that is stronger, more durable and of a higher quality than those currently available and which is relatively easy to service in the field.

### SUMMARY OF THE PRESENT INVENTION

The present invention provides an improved vehicle loudspeaker, or woofer, that is more durable and of a higher quality than those currently available and which can be easily serviced in the field. The loudspeaker includes a machined or cast aluminum basket that increases the strength and rigidity along with efficient cooling required to support a high-power/high-output speaker. An aluminum ring is provided for clamping the speaker assembly in place to the speaker frame and the speaker wires are connected to the speaker using a lug-lock system. The speaker utilizes a Faraday cage to reduce interference that otherwise would harm sensitive electronic components. In a second embodiment, a speaker is designed to utilize multiple individual magnets that are stacked in series/parallel configurations to increase gauss efficiency, provide a more consistent gauss field and voice coil cooling. In a third speaker embodiment, a multi-piece, cast aluminum basket is provided which supports the speaker's reactive and static weight while maintaining the voice coil assembly aligned inside a precision ground gap. The basket assembly has interchangeable parts that allow the speaker characteristics to be varied without having to retool the entire frame assembly.

The present invention thus provides an improved high power/high-output speakers, or woofers, that are more durable and more reliable then vehicle speakers currently available, is easily field serviceable and is readily modified to incorporate later developed improvements.

### DESCRIPTION OF DRAWINGS

For better understanding of the present invention as well as other objects and further features thereof, reference is made to the following description which is to be read in conjunction with the accompanying drawing therein:

FIG. 1 is an exploded view of a first embodiment of the speaker of the present invention;

FIG. 2 is a front elevational view of the speaker shown in FIG. 1;

FIG. 3 is a top view of the speaker shown in FIG. 2;

FIG. 4 is a bottom view of the speaker shown in FIG. 2;

FIG. 5 is a cross-sectional view along line 5-5 of FIG. 2;

FIG. 6 is a cross-sectional view along line 6-6 of FIG. 3;

FIG. 7 is an exploded view of a second embodiment of the speaker of the present invention;

FIG. 8 is a front elevational view of the speaker shown in FIG. 7;

FIG. 9 is a front elevational view of a third embodiment of the present invention;

FIG. 10 is a top view of the speaker shown in FIG. 9;

FIG. 11 is a rear view of the speaker shown in FIG. 9;

FIG. 12 is a bottom view of the speaker shown in FIG. 9;

FIG. 13 is a cross-sectional view along line 13-13 of FIG. 9; and

FIG. 14 is a cross-sectional view along line 14-14 of FIG. 10.

### DESCRIPTION OF THE INVENTION

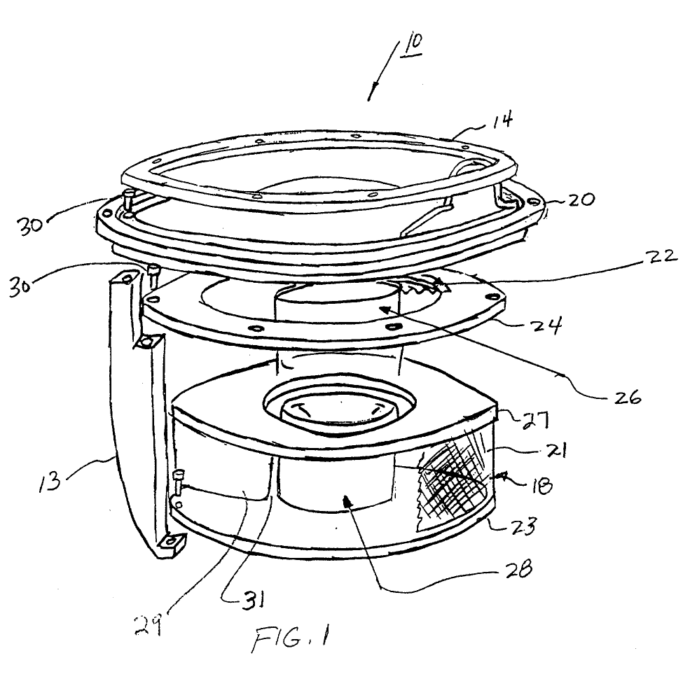

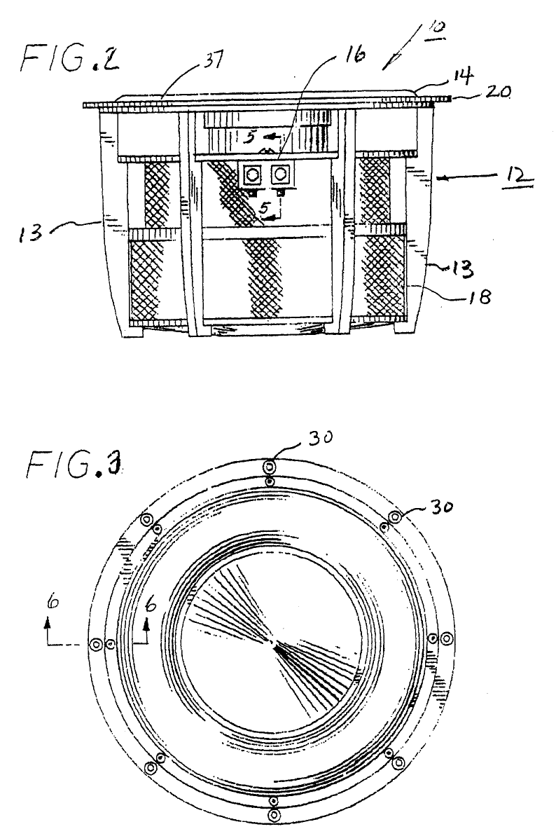

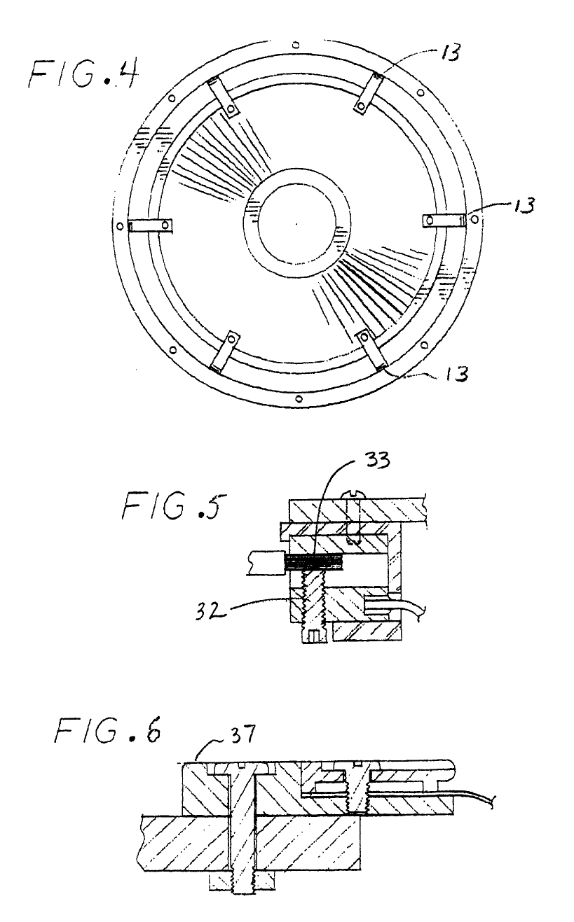

Referring now to FIGS. 1-6, a first embodiment of the speaker 10 of the present invention is illustrated and comprises a one piece basket 12 having vertical support or fin, members 13, aluminum clamping, or retaining ring 14, lug-lock terminals 16, Faraday cage 18, top plate 20, damper 22, damper platform 24, voice coil 26, pole piece 28, magnet 29 and a plurality of assembly screws 30.

Cast aluminum speaker basket 12 increases speaker strength and rigidity and provides efficient cooling, a feature that is required to support a high-power/high-output speaker.

The design of speaker 10 enables high reactive weights, well in excess of 60 pounds, along with static weights of up to 500 pounds to be supported while maintaining the internal voice coil 26 aligned inside a precision ground gap 31 formed by a pole piece 28, top plate 27 and magnet 29. Eight vertical support members, or fins, 13 and an open air passage in the center of pole piece 28 provide additional cooling to basket and voice coil 12. Fins 13 and air passages 36 extend the life expectancy of speaker 10 by a factor of 10 by acting as a forced air conversion cooling system (when speaker 10 is playing) to direct harmful heat away from the voice coil 26 and magnet 29 allowing the speaker 10 to operate cooler and more efficiently.

Lug-lock terminal system 16 connects the speaker wires to speaker 10 and provides for more efficient current transfer and mechanically solid wire connections that remain connected withstanding the vibrations that normally occur during driving. In this regard, machine screws 32 as shown in FIG. 5 are angled toward the back of terminal system 16, placing a large amount of resistive pressure on wires 33 to keep the wires secure within the connector even under extreme conditions.

The skin effect, which refers to the flow of electrical current on the outside instead of the inside of a wire, gives the terminal system 16 a distinct advantage since there is a greater surface area for the outside of the wires to transfer current to the terminal.

Aluminum ring 14 attaches to the top of speaker assembly 10 clamping the surround (flexible support of the conical diaphragm in open-diaphragm electrodynamic loudspeakers) 37 in place to the speaker frame comprising vertical support members 13 and top plate 20. Ring 14 provides uniform pressure around the entire perimeter to ensure surround 37 does not move during use. In addition, ring 14 allows the speaker to be serviceable in the field providing a simpler and safer assembly and disassembly since toxic glues are not utilized in contradistinction to conventional speaker assemblies.

Speaker Faraday cage 18 (a Faraday cage is an arrangement of parallel conductors acting as an electrostatic screen) consists of an aluminum mesh screen 21, provided to reduce interference that otherwise would harm sensitive electronic components, wrapped around a plurality of speaker magnets (only magnet 29 illustrated) attached to plate 27 and bottom plate 23 to form a ground shield that reduces the EMI (electro magnetic interference) and RFI (radio frequency interference) produced by the speaker while in use or at rest.

The speakers that form the present invention are typically used in vehicles that have one or more computers that control various electrical functions within the vehicle. Since the computers are sensitive to EMI and RFI, Faraday cage 18 reduces the interference caused by the electro and earth magnets conventionally used in speaker designs that would otherwise impact the computers and other electronic components. In addition, high output speakers, such as those of the present invention generate heat greater than 140 degrees Fahrenheit under extreme use. Faraday cage 18 also acts as a heatsink to help dissipate the excess heat generated by the speaker during normal operation thus cooling the vehicle motor structure and the magnet assembly.

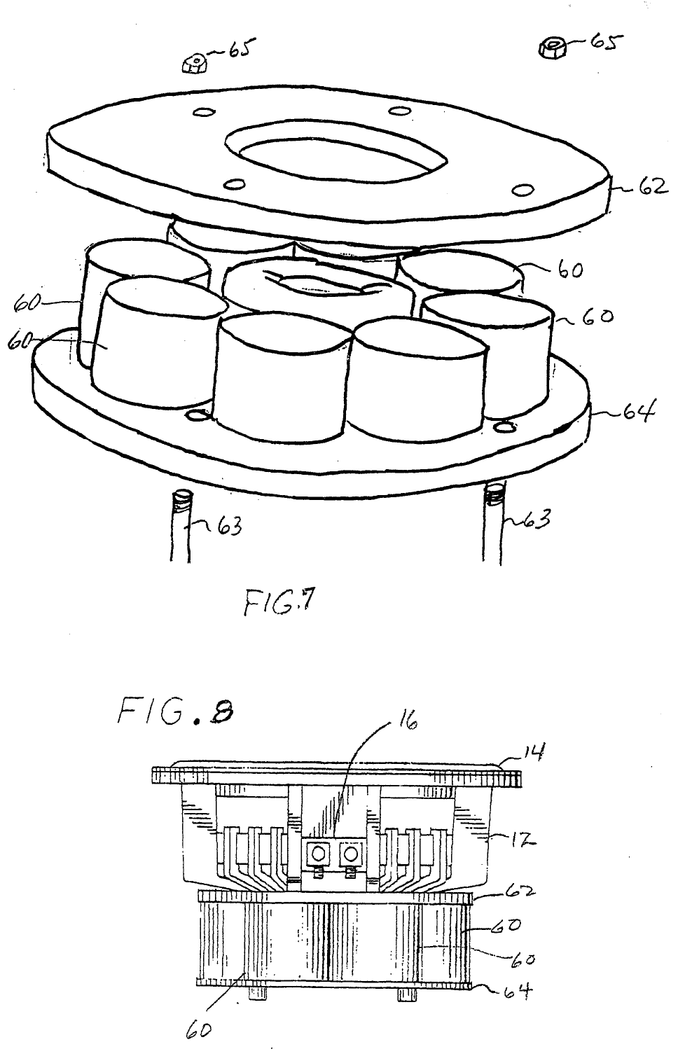

A second speaker embodiment of the present invention is shown in FIGS. 7 and 8 (note that the basic internal configuration of the speaker embodiment shown in FIGS. 1-6 is similar to that shown in the embodiment of FIGS. 7 and 8) and provides a cast basket, multi-element, speaker magnet structure to increase gauze efficiency and increased voice coil cooling over conventional speaker designs. Multiple individual magnets 60 are stacked in a series/parallel configuration and mounted in a 360° circle in between the perimeter of the top and bottom plates 62 and 64, respectively, of the speaker magnet structure. Plates 62 and 64 are joined by a plurality of assembly screws 63, (only two screws 63 shown) and nuts 65 (only two nuts 65 are shown). Using many individual magnets that are all summed together creates an essentially symmetrical magnetic flux density field while eliminating hot spots in the magnetic gap of the speaker. This enables the speaker cone assembly to move in a more efficient linear motion. Mounting the magnet stacks with a slight gap between them also increases the airflow and cooling around the voice coil that equates into increased speaker life and performance.

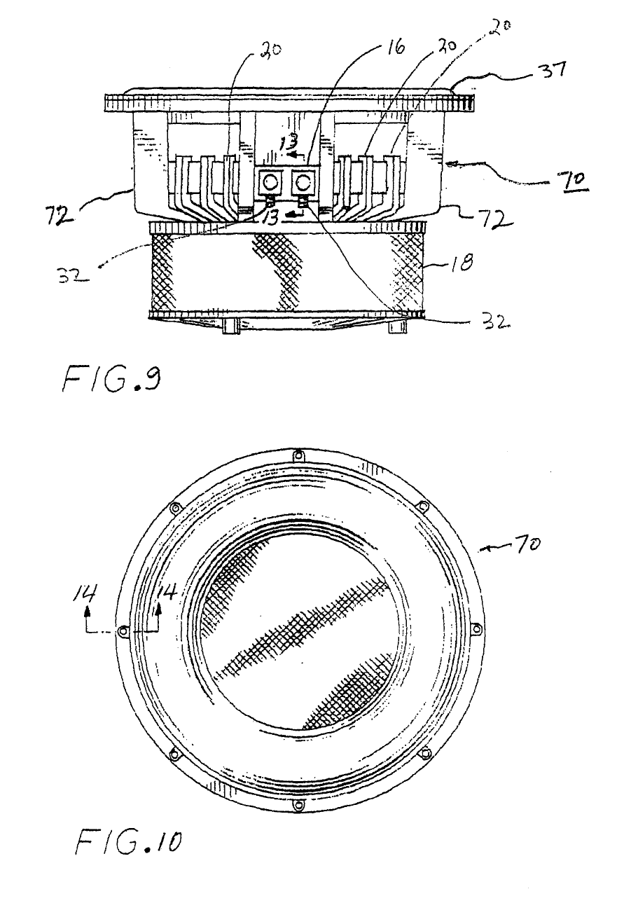

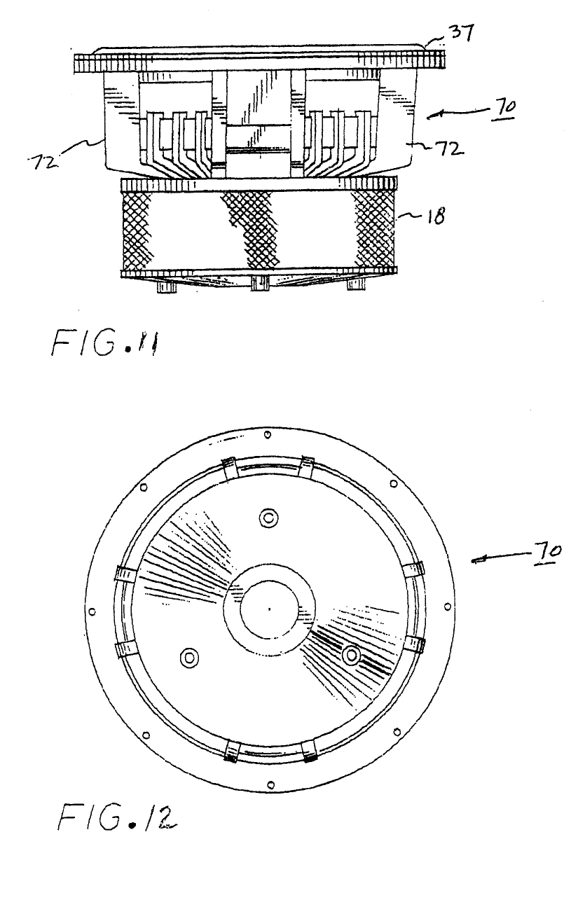

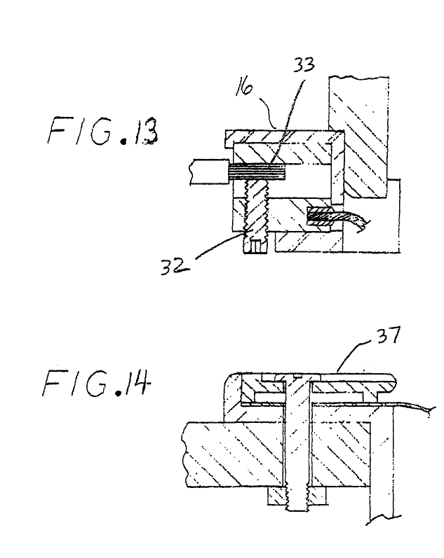

Referring to FIGS. 9-14, a third embodiment of the invention is illustrated. In particular, speaker 70 comprises a modular basket assembly having aluminum frame member, fabricated using a aluminum casting process, having a plurality of vertical support members 72. The frame member, and in particular, support members 72, provide the ability to support large amounts of reactive weight along with the speaker's static weight while keeping the voice coil assembly aligned inside a precision ground gap consisting of a pole piece, top plate and voice coil frame.

The basket frame assembly used in this embodiment has interchangeable parts that provides the ability to change the characteristics of the speaker design without having to retool the entire frame assembly.

It should be noted that the three embodiments noted above all include the Faraday cage principle described in detail with reference to the embodiment shown in FIGS. 1-6 and thus provide the advantage associated with their use.

While the invention has been described with reference to its preferred embodiments, it will be understood by those skilled in the art that various changes may be made and equivalents may be substituted for elements thereof without departing from the true spirit and scope of the invention. In addition, many modifications may be made to adapt a particular situation or material to the teachings of the invention without departing from its essential teachings.

WHAT IS CLAIMED IS:

1. A vehicle speaker comprising:
a frame member;
a basket member having a plurality of vertically extending fin members, a bridge member and damper platform, air passages being provided between the bridge member and said damper platform;
a ring member for clamping the surround to said frame member; and
a Faraday cage member coupled to said basket member for reducing EMI and RFI radiation interference.

2. The speaker of claim 1 wherein said Faraday cage member comprises a metal mesh screen.

3. The speaker of claim 2 further including a plurality of vertically extending support members for securing said basket member together.
